(19) United States
(12) Patent Application Publication
(10) Pub. No.: US 2012/0286264 A1
(43) Pub. Date: Nov. 15, 2012

(54) FLEXIBLE SEMICONDUCTOR DEVICE, METHOD FOR MANUFACTURING THE SAME AND IMAGE DISPLAY DEVICE

(76) Inventors: Takeshi Suzuki, Osaka (JP); Seiichi Nakatani, Osaka (JP); Koichi Hirano, Osaka (JP)

(21) Appl. No.: 13/519,668

(22) PCT Filed: Apr. 22, 2011
(86) PCT No.: PCT/JP2011/002367

§ 371 Date: Jun. 28, 2012

(30) Foreign Application Priority Data
May 14, 2010 (JP) 2010-112316

(51) Int. Cl. H01L 29/786; H01L 21/336

(52) U.S. Cl. 257/43; 257/52; 257/59; 438/158; 257/49; 257/72; 257/E29.273; 257/E21.412

(57) ABSTRACT

There is provided a method for manufacturing a flexible semiconductor device. The method of the present invention comprises the steps of: (a) preparing a metal foil having a concave portion; (b) forming a gate insulating film on a bottom face of the concave portion of the metal foil; (c) forming a semiconductor layer above the bottom face of the concave portion via the gate insulating film while making use of the concave portion as a bank member; and (d) forming a source electrode and a drain electrode such that they make contact with the semiconductor layer.

### TECHNICAL FIELD

The present invention relates to a flexible semiconductor device with its flexibility, and also a method for manufacturing the same. In particular, the present invention relates to the flexible semiconductor device which can be used as a TFT, and also the method for manufacturing the same. Furthermore, the present invention relates to an image display device using such a flexible semiconductor device.

### BACKGROUND OF THE INVENTION

There is a growing need for a flat-panel display for use in a computer with a wide spreading use of information terminals. With further advancement of informatization, there are also increasing opportunities in which information, which has been conventionally provided by paper medium, is digitized. Particularly, the needs for an electronic paper or a digital paper have been recently increasing since they are thin and light weight mobile display media which can be easily held and carried (see Patent document 1, described below).

Generally, the display medium of a flat panel display device is formed by using an element such as a liquid crystal, an organic EL (organic electroluminescence) and an electrophoresis. In such display medium, a technology which uses an active drive element (TFT element) as an image drive element has become a mainstream to secure a uniformity of the screen luminosity and a screen rewriting speed and so forth. For example, in the conventional display device for use in the computer, TFT elements are formed on a substrate wherein a liquid crystal element, an organic EL element or the like is sealed.

As a TFT element, semiconductors including a-Si (amorphous silicon) and p-Si (polysilicon) can be mainly used. These Si semiconductors (together with metal films, as necessary) are subjected to a multilayering process wherein each of a source electrode, a drain electrode and a gate electrode is sequentially stacked on the substrate, which leads to an achievement of the production of the TFT element.

Such method of manufacturing a TFT element using Si materials includes one or more steps with a high temperature, so that there is needed an additional restriction that the material of the substrate should resist a high process temperature. For this reason, it is required in practice to use a substrate made of a high heat-resistant material (e.g., a glass substrate). In the meanwhile, it may be possible to use a quartz substrate. However a quartz substrate is so expensive that an economical problem arises when scaling up of the display panels. Therefore, the glass substrate is generally used as the substrate for forming such TFT elements.

However, when the thin display panel as described above is produced by using the conventionally known glass substrate, there is a possibility that such display panel will have a heavy weight, lack flexibility and break due to a shock when it is fallen down. These problems, which are attributable to the formation of a TFT element on the glass substrate, are so undesirable in light of the needs for a portable thin display having lighter weight with the advancement of informatization.

From the standpoint of obtaining a substrate having flexibility and light weight to meet the needs for a lightweight and thin display, there is developed a flexible semiconductor device wherein TFT elements are formed on a resin substrate (i.e., plastic substrate). For example, Patent document 2 (see below) discloses a technique in which a TFT element is firstly formed on a substrate (i.e., glass substrate) by a process which is almost the same as conventional process, and subsequently the TFT element is peeled from the glass substrate so that it is transferred onto a resin substrate (i.e. plastic substrate). In this technique, the glass substrate wherein the TFT element is provided thereon is adhered to a resin substrate via a sealing layer (e.g., an acrylic resin layer), and subsequently the glass substrate is peeled thereoff. In this way, the TFT element is transferred onto the resin substrate.

In the method for manufacturing a TFT element using such a transference process, there is, however, a problem associated with the peeling of the substrate (i.e., glass substrate). In other words, it is necessary to perform an additional treatment to decrease the adhesion between the substrate and the TFT element upon the peeling of the substrate from the resin substrate. Alternatively it is necessary to perform an additional treatment to form a peel layer between the substrate and the TFT element and thus also necessary to physically or chemically remove the peel layer afterward. These additional treatments can make the process complicated, so that another problem associated with the productivity could also be caused.

### PATENT DOCUMENTS (PRIOR ART PATENT DOCUMENTS)

[Patent document 1] Japanese Unexamined Patent Publication (Kokai) No. 2007-67263; and
[Patent document 2] Japanese Unexamined Patent Publication (Kokai) No. 2004-297084.

### SUMMARY OF THE INVENTION

### Problems to be Solved by the Invention

In the production of the flexible semiconductor device, it is considered to directly form a TFT element on the resin substrate (or plastic plate), not transferring the TFT element onto the resin substrate. In this case, a peeling step (or removing step) of the supporting plate (i.e., glass substrate) after the transferring becomes unnecessary, and thus the flexible semiconductor device can be simply and easily manufactured.

However, since the resin substrate made of the acrylic resin or the like has a low heat-resistance, the process temperature is restricted to be kept as low as possible upon producing the TFT elements. Therefore, the TFT element which has been directly formed on the resin substrate can cause a problem in terms of a lowered TFT performance, as compared with that of the TFT elements obtained through the transference process.

For example, it is desired to subject the semiconductor material to a heat treatment in order to improve the semiconductor properties (e.g., mobility). However, in the case where the TFT element is directly formed on the resin substrate, it is difficult to adopt such heat treatment because of the restricted process temperature. Moreover, in order to decrease a gate voltage, it is desired to use, as a gate insulating film, an inorganic oxide with not only its high dielectric strength voltage, but also its thin thickness and moreover its high dielectric constant. However, such inorganic oxide can cause such a challenging problem to be greatly improved in terms of the production thereof that it is not easy to perform a machining process (e.g., laser machining process for forming a hole) due to the fact that the inorganic oxides generally have a densified form and a high chemical stability. In particular, such problem becomes severe when it comes to the flexible semiconductor device used for a large sized screen.

Moreover, the positioning of the semiconductor layer can be important from the viewpoint of the production of the flexible semiconductor device. When the accuracy of the positioning is inferior, no desirable TFT performance can be obtained, which could cause another problem in terms of a manufacturing yield of the flexible semiconductor device.

Furthermore, the flexible semiconductor device, which is composed of a plurality of laminated layers, is required to prevent the layers from causing their misalignment to attain an improved tight adhesiveness (or firm adhesiveness) between the layers.

The inventors of the present application tried to dissolve such problems not by following up the conventional way, but by focusing on a new way. The present invention has been accomplished in view of the above matters, and thus a main object of the present invention is to provide a method for manufacturing a flexible semiconductor device which is excellent in productivity, and also to provide a flexible semiconductor device with a high performance by such method.

### Means for Solving the Problem

In order to solve the above-mentioned problems, the present invention provides a method for manufacturing a flexible semiconductor device, the method comprising the steps of:

(A) preparing a metal foil having a concave portion;

(B) forming a gate insulating film (insulating layer) on a bottom face of the concave portion;

(C) forming a semiconductor layer over the bottom face of the concave portion of the metal foil via the gate insulating film while making use of the concave portion as a bank member; and

(D) forming a source electrode and a drain electrode such that they make contact with the semiconductor layer.

It is preferred in the manufacturing method of the present invention that the metal foil having the concave portion is subjected to a pattering process, and thereby a gate electrode is formed from the metal foil.

For one thing, the manufacturing method of the present invention is characterized in that the metal foil having the concave portion is utilized. That is, the flexible semiconductor device is suitably manufactured by utilizing the concave portion of the metal foil. More specifically, the concave portion of the metal foil to be used as the gate electrode is utilized as the bank member, and thereby the semiconductor layer is formed such that the semiconductor layer is accommodated in the concave portion.

The term “flexible” of the “flexible semiconductor device” used in the present description substantially means that the semiconductor device has such flexibility characteristic that the device can be inflected. The “flexible semiconductor device” of the present invention may also be referred to as “flexible semiconductor element”, in view of the structure thereof.

The term “bank member” used in the present description, which is derived from the bank (i.e., the slope of land adjoining a body of water), substantially means a member serving as “positioning” of raw materials/materials of the semiconductor layer. The “concave portion” which gives the bank member is one provided in the metal foil with the intention to perform such “positioning”, so that it should be noted that the “concave portion” does not correspond to a scratch, a dimple or the like which could be inevitably or accidentally formed upon the producing process of the metal foil.

In one preferred embodiment, the concave portion of metal portion is formed such that it has a tapered shape. For example, the concave portion having the tapered shape is formed by subjecting the metal foil to a photolithography process and an etching process. More specifically, the concave portion with its tapered shape is formed by performing a wet etching in the photolithography process.

Preferably, the manufacturing method of the present invention further comprises a step (E) performed after the step (D), the step (E) being one for forming a resin film layer having flexibility such that it covers the semiconductor layer, the source electrode and the drain electrode. In this regard, it is preferred that the resin film layer is formed over the metal foil by laminating a resin film over the metal foil, and thereby a part of the resin film interfits (interdigitates) with the concave portion of the metal foil (more specifically, “concave portion of gate structure”). For example, a resin film layer precursor may be used, in which case the resin film layer precursor is laminated onto the metal foil while being pressed so that a part of the resin film layer precursor is embedded into the concave portion. Such formation of the resin film layer can be performed by a roll-to-roll process.

In one preferred embodiment, the semiconductor layer formed above a layer of the metal foil is subjected to a heat treatment after the step (C). It is preferred that the semiconductor layer formed above the metal foil layer (more specifically “semiconductor layer provided on the insulating film formed on the metal foil”) is subjected to an annealing treatment by irradiating it with a laser at a point in time between steps (C) and (D). This heating treatment can cause the modification of a film quality or property of the semiconductor layer, which leads to an achievement of the improved properties of the semiconductor layer. For example, the modification of the semiconductor layer makes it possible to improve the crystallinity of the semiconductor layer. The term “anneal treatment” used in the present description substantially means a heat treatment intended to improve or stabilize the properties such as “crystalline state”, “degree of crystallization” and/or “mobility”.

In another preferred embodiment, the gate insulating film provided on the metal foil layer is subjected to a heat treatment after the step (B). Preferably, the insulating film provided on the metal foil is subjected to an annealing treatment by irradiating the insulating film with a laser. Such treatment of the gate insulating film may be performed at a point in time not only between the step (B) and the step (C), but also between the step (C) and the step (D). In other words, not only the gate insulating film may be directly subjected to the heat treatment (especially “annealing treatment”), but also the gate insulating film may be subjected to the heat treatment (especially “annealing treatment”) by a heat from the semiconductor layer upon the heating treatment of the semiconductor layer.

In still another preferred embodiment, the gate insulating film formed of an inorganic material is formed in the step (B). For example, the gate insulating film may be formed by a sol-gel process. Alternatively, the gate insulating film may be formed by subjecting the metal foil (gate electrode) to an anodic oxidation treatment.

The present invention further provides a flexible semiconductor device obtained by the above manufacturing method. Such flexible semiconductor device comprises a gate structure composed of a gate electrode formed of a metal foil and a gate insulating film provided on the gate electrode,

wherein a concave portion serving as a bank member is provided in a surface of the gate structure;

a semiconductor layer is provided over a bottom face of the concave portion such that the semiconductor layer is accommodated in the concave portion; and

a source electrode and a drain electrode are in contact with the semiconductor layer.

For one thing, the flexible semiconductor device of the present invention is characterized in that the concave portion serving as the bank member, is provided on the surface region of the gate structure, and that the formed semiconductor layer is located to be housed within the concave portion.

As described above, the “concave portion serving as a bank member” corresponds to a locally hollow portion provided in the metal foil with a view to the positioning of the material. Especially, the “concave portion serving as a bank member” corresponds to a locally hollow portion which has functioned as the positioning member for the material of the semiconductor layer. In other words, the flexible semiconductor device of the present invention can be one in which a locally formed concave portion accommodating the semiconductor layer is provided. According to the present invention, the concave portion having a tapered shape is provided wherein an angle between a sidewall face of the concave portion and a top face extending continuously from the sidewall face is an obtuse angle.

The flexible semiconductor device of the present invention preferably a resin film layer. In this case, the resin film layer which has flexibility is provided over the gate structure such that the semiconductor layer, the source electrode and the drain electrode are covered with the resin film layer. It is preferred that the resin film layer has a protruding portion which is interfitted with the concave portion of the gate structure. More specifically, the protruding portion of the resin film layer is complementarily interfitted with the concave portion of the gate structure. In other words, the protruding portion of the resin film layer and the concave portion of the gate structure have complementary form with respect to each other, and thereby the space of the concave portion (i.e., concaved space other than the filled portion of the semiconductor layer in the concave portion) is filled with the body of the protruding portion of the resin film layer.

The semiconductor layer in the flexible semiconductor device of the present invention may comprise a silicon or an oxide semiconductor (e.g., ZnO or InGaZnO).

In the flexible semiconductor device of the present invention, the gate insulating film is made of an inorganic material. Preferably, the gate insulating film may be one obtained by locally oxidizing the metal foil of the gate electrode. In this case, the gate electrode may comprise a valve metal material, and thus the gate insulating film may be an anodically-oxidized film of the valve metal. In another embodiment, the gate insulating film may be an oxide film obtained from a sol-gel process.

The present invention further provides an image display device in which the above flexible semiconductor device is used. Such image display device comprises:

the flexible semiconductor device; and

an image display unit composed of a plurality of pixels, the unit being provided over the flexible semiconductor device,

wherein the concave portion serving as the bank member is provided in the surface of the gate structure of the flexible semiconductor device; and

the semiconductor layer of the flexible semiconductor device is provided over the bottom face of the concave portion.

### Effect of the Invention

In accordance with the manufacturing method of the present invention, the semiconductor layer can be suitably arranged by the using of the metal foil having the concave portion. Particularly, the semiconductor layer can be relatively easily formed at the desired position since the concave portion can serve as the bank for the “positioning” thereof. Specifically, the following matters (I) and (II) are possible:
(I) In a case where the semiconductor layer is formed through a thin film formation process or a printing process, the deposition of the semiconductor materials can be performed within the concave portion and thus such deposited materials may be used as the semiconductor layer. This makes it possible to perform an effective positioning of the semiconductor layer formation; and
(II) In a case where the raw material for the semiconductor layer is in a paste form or in a liquid form, the supplied raw material to the concave portion can be held in place without being allowed to flow out of the concave portion. This makes it possible to facilitate the formation of the semiconductor layer at the predetermined position (i.e., at the concave portion).
   Especially as for the above (II), the concave portion can also serve to hold the liquid raw materials of the semiconductor upon the formation of the semiconductor layer, and thus the concave portion can function as the bank for “storing” (or as “storage bank”) as well as the bank for “positioning” (as “positioning bank”).

According to the manufacturing method of the present invention, the metal foil with the concave portion serving as the positioning bank can be used as the constituent material of the electrodes i.e., the constituent element of the flexible semiconductor device (specifically “gate electrode”). This means that there is no need to finally remove or peel off the metal foil which has contributed to the formation of the semiconductor layer, and thereby the TFT element can be manufactured by simple and easy process, which leads to an achievement of the improved productivity thereof.

According to the manufacturing method of the present invention, a part of the resin film layer is forced to be interfitted with the concave portion of the bank member, and thereby making it possible to provide an effect of preventing the resin film layer from to be peeled off. Such effect is due to the complementary interfitting between “protruding portion of the resin film layer” and “concave portion of the gate structure”. Such structural feature can improve the tight adhesiveness in the resin film layer. In other words, the present invention can improve the tight adhesiveness of the laminated structure by the “concave portion” serving as the bank member.

The improved tight adhesiveness of the laminated structure particularly provides an advantageous effect when the flexible semiconductor is subjected to a bent condition (e.g., a roll-to-roll process). That is, the peeling of the layer can be effectively prevented even when the laminated structure is subjected to a severe manufacturing condition where the peeling is induced. This also leads to the improved productivity.

Since the lamination of the obtained flexible semiconductor device is firmly hold, a degradation of the performance resulted from the “peeling” can be prevented. The flexible semiconductor device is usually used in a bent condition. In this regard, the present invention can suitably prevent such peeling by the concave portion, which leads to an achievement of a high bending-resistance of the flexible semiconductor device.

Moreover, according to the present invention, the heating (particularly preferably “anneal heating”) of the gate insulating film and/or the semiconductor layer can be suitably performed to improve the properties thereof, since the metal foil is used as the base materials for the concave portion serving as the “bank” in spite of the flexible semiconductor device. That is, there can be obtained an effectively improved performance in the flexible semiconductor device.

### BRIEF DESCRIPTION OF DRAWINGS

FIG. 1(a) schematically illustrates a perspective cross sectional view of a flexible semiconductor device 100 according to an embodiment of the present invention, showing the structure of the device. FIG. 1(b) illustrates a top plan view for explaining a transistor structure in the concave portion 50 of the device.

FIGS. 2(a) to 2(d) illustrate cross-sectional views showing the steps in a manufacturing process of a flexible semiconductor device 100 according to an embodiment of the present invention.

FIG. 3(a) illustrates a part of cross-sectional view showing the step in a manufacturing process of a flexible semiconductor device 100 according to an embodiment of the present invention. FIG. 3(b) illustrates a top plan view of a part of the construction shown in FIG. 3(a), seen from above.

FIGS. 4(a) to 4(c) illustrate cross-sectional views showing the steps in a manufacturing process of a flexible semiconductor device 100 according to an embodiment of the present invention.

FIG. 5 schematically illustrates an embodiment of “concave portion” which functions as a positioning bank member for determining the formed position of a semiconductor layer.

FIG. 6 illustrates a circuit diagram in a drive circuit of an image display device according to an embodiment of the present invention.

FIG. 7 schematically illustrates a cross-sectional view of an image display device according to the present invention.

FIG. 8 schematically illustrates a cross-sectional view of an image display device equipped with a color filter according to the present invention.

FIGS. 9(a) to 9(e) illustrate cross-sectional views schematically showing the steps in a manufacturing process of an image display device according to the present invention.

FIGS. 10(a) to 10(d) illustrate cross-sectional views schematically showing the steps in a manufacturing process of an image display device equipped with a color filter according to the present invention.

FIG. 11 schematically illustrates an embodiment where a flexible semiconductor device 100 according to an embodiment of the present invention is produced through the roll-to-roll process.

FIG. 12 illustrates an enlarged sectional view of a part of a flexible semiconductor device 100 which has been wound up by the roller 230.

FIG. 13 illustrates an example of a product (an image display part of a television) wherein a flexible semiconductor device of the present invention is used.

FIG. 14 illustrates an example of a product (an image display section of a cellular phone) wherein a flexible semiconductor device of the present invention is used.

FIG. 15 illustrates an example of a product (an image display section of a mobile personal computer or a laptop computer) wherein a flexible semiconductor device of the present invention is used.

FIG. 16 illustrates an example of a product (an image display section of a digital still camera) wherein a flexible semiconductor device of the present invention is used.

FIG. 17 illustrates an example of a product (an image display section of a camcorder) wherein a flexible semiconductor device of the present invention is used.

FIG. 18 illustrates an example of a product (an image display section of an electronic paper) wherein a flexible semiconductor device of the present invention is used.

### DETAILED DESCRIPTION OF THE INVENTION

Hereinafter, some embodiments of the present invention will be illustrated with reference to Figures. In the following Figures, the same reference numeral indicates the element which has substantially the same function for simplified explanation. The dimensional relationship (length, width, thickness and so forth) in each Figure does not reflect a practical relationship thereof.

Each “direction” referred to in the present description means the direction based on the spatial relationship between the metal foil 70 (gate electrode 12) and the semiconductor layer 20, in which each of upward direction and downward direction is mentioned relating to the direction in the drawings for convenience. Specifically, the upward direction and the downward direction respectively correspond to the upward direction and the downward direction in each drawing. The side on which the semiconductor layer 20 is formed based on the metal foil 70 (gate electrode 12) is referred to as “upward direction”, and whereas the side on which the semiconductor layer 20 is not formed based on the metal foil 70 (gate electrode 12) is referred to as “downward direction”.

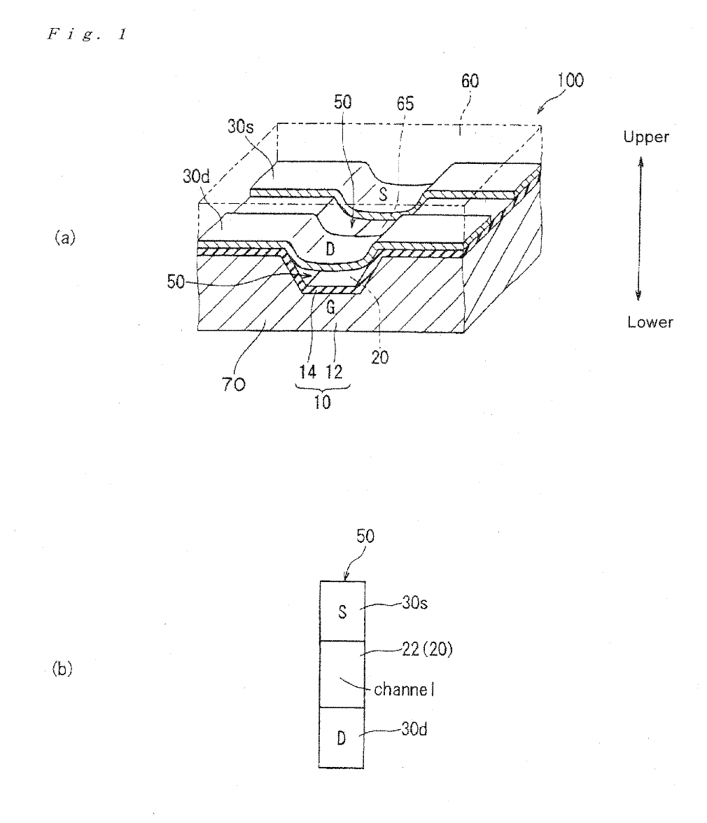

Referring to FIGS. 1 (a) and 1(b), a flexible semiconductor device 100 according to an embodiment of the present invention will be explained. FIG. 1 (a) is a perspective view schematically illustrating the structure of the flexible semiconductor device 100 of the present invention. FIG. 1 (b) shows a relationship among a source (S), a channel and a drain (D) of the flexible semiconductor device 100.

The flexible semiconductor device 100 according to the embodiment of the present invention has flexibility. As shown in FIG. 1(a), the flexible semiconductor device 100 comprises a gate electrode 12 formed of a metal foil 70 and a gate insulating film 14 provided on the gate electrode 12. The gate structure 10 of the flexible semiconductor device is composed of the gate electrode 12 and the gate insulating film 14. A surface of the gate structure is provided with a concave portion serving as a bank member.

At the bottom face of the concave portion 50 provided in the gate structure 10, a semiconductor layer 20 made of semiconductor materials is provided. Particularly, the semiconductor layer 20 is located so as to occupy at least a part of an internal space of the concave portion 50. In the embodiment shown in FIG. 1(a), the illustration of the semiconductor layer 20 is omitted so as to clearly show the concave portion 50. On the surface (upper surface) of the semiconductor layer 20, a source electrode 30s and a drain electrode 30d are provided. In the present invention, the concave portion 50 functions as a bank member. That is, the concave portion 50 functions as a positioning bank which determines the formed location of the semiconductor layer during the formation thereof. Particularly in a case where the semiconductor raw material is in a liquid form, the concave portion 50 additionally functions as a storage bank.

A resin film layer 60 is provided over the gate structure 10 such that the source electrode 30s, the drain electrode 30d and the semiconductor layer 20 are covered with the resin film layer. As shown, the resin film layer 60 is shown by a dotted line so as to clearly show the concave portion 50. The resin film layer 60 is provided with a protruding portion 65 (i.e., bulge portion) interfitted with the concave portion 50. As can be seen from FIG. 1(a), the protruding portion 65 of the resin film layer 60 and the concave portion 50 interdigitate with each other to form a complementary form in the flexible semiconductor device 100 of the present invention. Thus, the interdigitate structure between the protruding portion 65 and the concave portion 50 makes it possible to improve the tight adhesiveness between the resin film layer 60 and the gate structure 10. In other words, the improved adhesion of the laminated structure in the flexible semiconductor device 100 is achieved due to the presence of the concave portion 50.

The semiconductor layer 20 according to the present invention is obtained by allowing the concave portion to serve as the bank. For example, in a case where the formation of the semiconductor layer is performed at a concaved region in a thin film formation process or a printing process, the semiconductor material can deposit in the concave portion 50 regardless of the any supply deviation of the raw material, and thereby the deposited material can be suitably utilized as the semiconductor layer. Therefore, the concave portion 50 is capable of functioning as the positioning bank which determines the formed location of the semiconductor layer (see FIG. 5). For example, in a case where the semiconductor layer 20 made of silicon (Si) is formed, it be formed by supplying the liquid silicon into the concave portion 50, in which case the concave portion 50 can also function as a storage for the liquid silicon. In other words, in a case of the semiconductor raw material being in a paste form or in a liquid form, the concave portion 50 can not only serve as the “positioning member” which functions to determine the positioning of the semiconductor raw material, but also serve as the “storage bank” which functions to store (reserve) the supplied semiconductor raw material.

As a semiconductor material for the semiconductor layer 20 in the flexible semiconductor device of the present invention, the above-mentioned silicon (Si) may be used, but any other suitable materials may also be used. For example, the semiconductor layer may be made of the semiconductor material such as germanium (Ge), or an oxide semiconductor material. The oxide semiconductor may be an elementary oxide such as ZnO, SnO₂, In₂O₂ and TiO₂, or a composite oxide such as InGaZnO, InSnO, InZnO and ZnMgO. As needed, a compound semiconductor may also be used, in which case a compound thereof is for example GaN, SiC, ZnSe, CdS, GaAs and so forth. Furthermore, an organic semiconductor may also be used, in which case an organic compound thereof is for example pentacene, poly-3-hexyl-thiophene, porphyrin derivatives, copper phthalocyanine, C60 and so forth.

The gate insulating film 14 is made of inorganic materials in the flexible semiconductor device of the present invention. For example in a case of the semiconductor layer 20 made of silicon (Si), the gate insulating film 14 may be a silicon oxide film (SiO₂) or a silicon nitride film. The gate insulating film 14 can be formed by a sol-gel process. Alternatively, the gate insulating film 14 may be an oxide film formed by anodically oxidizing the gate electrode 12. In this regard, in a case where the gate electrode is made of a valve metal, the gate insulating film is preferably an anodically-oxidized film of the valve metal.

The structure around the concave portion 50 in the flexible semiconductor device of the present invention, when seen from the above, can be illustrated as shown in FIG. 1 (b). The semiconductor layer 20 is provided over the bottom face of the concave portion 50 (i.e., over the lower face of the concave portion), and the source electrode 30s and the drain electrode 30d are in contact with the top surface of the semiconductor layer 20. At the lower surface of the semiconductor layer 20 (i.e., at the bottom surface of the semiconductor layer), there is provided the gate insulating film 14 and the gate electrode 12. Thus, a portion of the semiconductor layer 20, which is located between the source electrode 30s and the drain electrode 30d, can function as a channel region 22, which thus provides the device with a transistor (a thin-film transistor: TFT).

The resin film layer 60 according to the flexible semiconductor device of the present invention is made of resin material which has flexibility. Particularly, the resin film layer 60, which can also serve as a supporting substrate for the gate structure 10, may be made of thermosetting resin materials or thermoplastic resin materials which provide the film layer with flexibility after being cured. Examples of such resin materials include, for example, an epoxy resin, a polyimide (PI) resin, an acrylic resin, a polyethylene terephthalate (PET) resin, a polyethylene naphthalate (PEN) resin, a polyphenylene sulfide (PPS) resin, polyphenylene ether (PPE) resin, a fluorinated resin (e.g., PTFE), a liquid crystal polymer, a composite thereof and the like. Alternatively, the resin film layer 60 may be made of an organic/inorganic-hybrid material which contains polysiloxane. The resin materials as described above are excellent in the dimensional stability and thus are preferably used as flexible materials of the flexible semiconductor device.

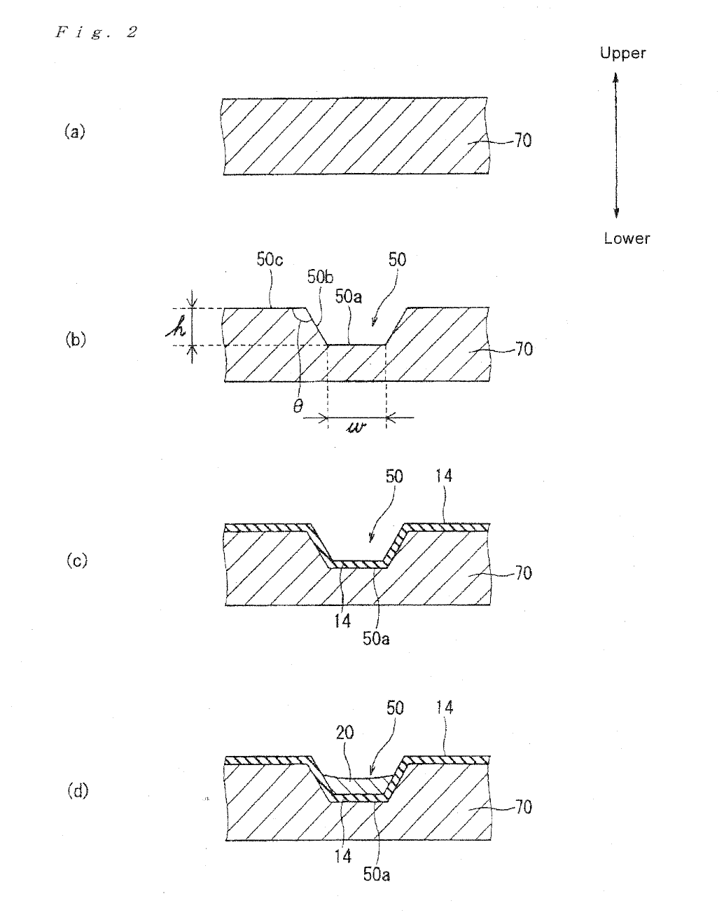

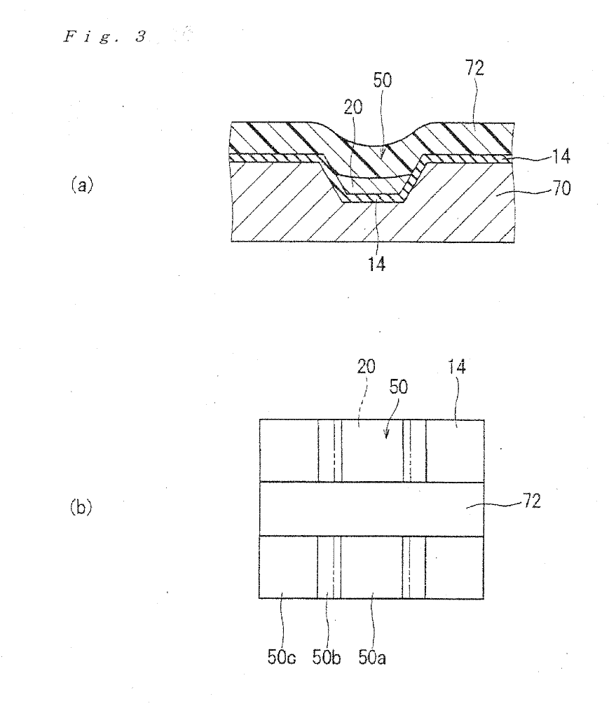

Next, with reference to FIGS. 2(a) to 2(d), FIGS. 3(a), 3(b) and FIGS. 4(a) to 4(c), the manufacturing method of the flexible semiconductor device 100 according to the present invention will be explained. FIGS. 2(a) to 2(d), FIGS. 3(a), 3(b) and FIGS. 4(a) to 4(c) respectively show cross-sectional views illustrating the steps in the manufacturing process of the flexible semiconductor device 100.

Upon carrying out the manufacturing method of the present invention, the step (A) is firstly performed. That is, a metal foil having a concave portion therein is prepared.

Specifically, a metal foil 70 is firstly provided as shown in FIG. 2(a). For example, the metal foil 70 may be a copper foil or an aluminum foil. The metal foil 70 has a thickness in the range of about 1 μm to about 500 μm and preferably in the range of about 3 μm to about 40 μm, for example.

Next, as shown in FIG. 2(b), a concave portion 50 is formed in the metal foil 70. For example, the concave portion 50 can be formed in the metal foil 70 by a combination of a photolithography process and an etching process. More detailed explanation about this is as follows: First, a photoresist film is formed on the whole surface of the metal foil 70 by using of photoresist materials such as a dry film or liquid type one. Then, a part of the photoresist film, which corresponds to the position of the concave portion 50 to be formed, is removed by subjecting to a pattern-exposure process using a photomask having a desired pattern, followed by a development process. Such removing treatment provides the photoresist with an opening. Thereafter, the metal foil on which the opening of the photoresist is provided is immersed in an etching solution, and then the photoresist film is removed. As a result, there is finally formed the concave portion 50 in the metal foil 70. For example, the etching solution may be suitably selected depending on the kind of the metal foil. Just as an example, a solution of ferric chloride, or a solution of sulfuric acid and hydrogen peroxide may be used in a case where of a copper foil. In another case of an aluminum foil, a mixed solution of phosphoric acid, acetic acid and nitric acid may be used. As shown in FIG. 2(b), the concave portion 50 is composed of a bottom face 50a, sidewall faces 50b and top faces 50c wherein the sidewall faces are inclined ones. In other words, the concave sportion 50 has a tapered shape according to the flexible semiconductor device of the present invention. The angle θ between the sidewall face 50b and the top face 50c is an obtuse angle. For example, the angle θ is in the range of about 100 degrees to about 170 degrees, preferably in the range of about 110 degrees to about 160 degrees (see FIG. 2(b)). The bottom width “w” of the concave portion as shown in FIG. 2(b) is preferably in the range of about 1 μm to about 1 mm, more preferably in the range of about 10 μm to about 300 μm. The depth (or height) “h” of the concave portion as shown in FIG. 2(b) is preferably in the range of about 0.5 μm to about 100 μm, more preferably in the range of about 2 μm to about 20 μm.

Subsequent to the formation of the concave portion, an insulating layer 14 is formed on the surface of the metal foil 70 alongside the surface of the concave portion 50 as shown in FIG. 2(c). That is, the step (B) of the manufacturing method of the present invention is performed. The thickness of the formed insulating layer 14 is in the range of about 30 nm to about 2 μm. In this regard, a part of the insulating layer 14, which is located on the bottom face 50a of the concave portion 50, serves as a gate insulating film. For example, the insulating layer 14 may be a silicon oxide layer. In such case, a thin film made of silicon oxide may be formed with using TEOS, for example.

The insulating layer 14 having the gate insulating film in a part thereof can be formed of an inorganic material. That is, even though an organic insulating film is generally used as the gate insulating film in the flexible semiconductor device wherein a resin substrate is used as a supporting substrate, the present invention makes it possible to use an inorganic insulating film as the gate insulating film, which leads to an improvement of the transistor performance of the flexible semiconductor device 100.

The reason for the improved performance of the transistor is that the gate insulating film made of the inorganic material not only has an improved dielectrics strength voltage even if being in a thin thickness, but also has a higher permittivity, compared with the case of the gate insulating film made of the organic material. According to the TFT structure of the present invention, the insulating layer 14 is provided over the surface of the metal foil 70, which makes it possible to lower the restriction in terms of the process for forming the insulating layer 14. This means that, the present invention enables the readily formation of the gate insulating film made of an inorganic material. Moreover, after the formation of the insulating layer 14 on the metal foil 70, the insulating layer 14 can be subjected to an annealing treatment (i.e., thermal annealing treatment) to improve the quality thereof, since the metal foil 70 is located beneath the insulating layer 14.

Moreover, in a case where the metal foil 70 is made of aluminum, the insulating layer 14 can be formed by locally and anodically oxidizing the surface region of the metal foil 70. The insulating layer formed by the locally anodic oxidation may have the thickness in the range of about 30 nm to about 200 nm. Any suitable chemical conversion solutions can be used for the anodic oxidation of the aluminum, and thereby a dense and very thin oxidized film can be formed. For example, as the chemical conversion solution, a “mixed solution of aqueous tartaric acid solution and ethylene glycol” with an adjusted pH of around the neutral value by using of ammonia, may be used. The metal foil 70 from which the insulating layer 14 can be formed by the anodic oxidation is not only aluminum foil, but also any suitable metal foil which has a good electric conductivity and is capable of readily forming a dense oxide. For example, the metal foil 70 may be a valve metal. Examples of the valve metal include, but not limited to, at least one metal selected from the group consisting of aluminum, tantalum, niobium, titanium, hafnium, zirconium, molybdenum and tungsten, or an alloy thereof. In a case where the anodic oxidation is adopted, there can be provided an advantage in that an oxide film with an even thickness can be formed on the surface even when the bank portion has a complicated shape. Also, in the case of the anodic oxidation, there can be provided another advantage in that a gate insulating film with a higher permittivity can be formed, compared with that of a silicon oxide film.

Moreover, the material of the metal foil 70 is not limited to the valve metal material (e.g., aluminum material), but the metals of the foil may be those capable of giving an oxide film which is uniformly coated on the surface of the foil by an oxidation. Therefore, a metal other than the valve metal may be used. In this regard, the oxidation process of the metal foil 70 can be performed by a thermal oxidation (surface oxidation by heating treatment) or chemical oxidation (surface oxidation by an oxidizing agent) instead of the anodic oxidation.

Alternatively, the insulating layer 14 can be formed by performing a sol-gel process. The insulating layer formed by the sol-gel process may have the thickness in the range of about 100 nm to about 1 μm. In this case, the insulating layer 14 may be a silicon oxide film, for example. Just as example of the case of the sol-gel process for forming the silicon oxide, it can be formed by evenly applying a colloidal solution (a sol-liquid), which has been prepared by stirring a mixture solution of tetraethoxysillane (TEOS), methyltriethoxysilane (MTES), ethanol and dilute hydrochloric acid (0.1 wt %) for 2 hours at room temperature, onto the metal foil by a spin-coating process and then is subjected to a heat treatment at 300° C. for 15 minutes. According to such sol-gel process, there is provided an advantage in that it can produce a gate insulating film with a high permittivity (e.g., such as the silicon oxide film, a hafnium oxide film, an aluminum oxide film and a titanium oxide film with a high permittivity).

Subsequent to the formation of the insulating layer, as shown in FIG. 2(d), a semiconductor layer 20 is formed over the bottom face 50a of the concave portion 50. That is, the step (C) in the manufacturing method of the present invention is performed. The formed semiconductor layer 20 may have a thickness in the range of about 30 nm to about 1 μm, preferably in the range of about 50 nm to about 300 nm. In the step (C), the semiconductor layer 20 can be suitably formed since the concave portion 50 can function as the bank member for the “positioning” of the semiconductor layer.

For example in a case where the semiconductor layer is formed by a thin film formation process or a printing process, the deposition of the semiconductor materials can be performed in the concave portion 50, and thereby such deposited materials may be suitably utilized as the semiconductor layer. In this case, the concave portion 50 can serve to determine the positioning of the semiconductor layer formation (see FIG. 5). In other words, the concave portion 50 serves as the bank member for the “positioning” of the semiconductor layer. Examples of the thin film formation process include, but not limited to, a vacuum deposition process, a sputtering process, a plasma CVD process and the like. While on the other hand, examples of the printing process include a relief printing process, a gravure printing process, a screen printing process, an ink jet process and the like.

In a case where the raw material for the semiconductor layer 20 is in a liquid form and thus it is supplied to the bottom face 50a of the concave portion 50, the supplied raw material can be held in the concave portion 50 while preventing the material from flowing out of the concave portion 50. That is, in the case where the raw material for the semiconductor layer is in a liquid form or in a paste form, the concave portion 50 serves as the bank member for the “storing” of the raw material in addition to the “positioning” of the semiconductor layer.

The formation of the semiconductor layer will be now specifically explained. In a case where the semiconductor layer 20 is formed as a silicon layer, a solution material containing a cyclic silane compound (for example, a toluene solution of cyclopentasilane) is applied over the bottom face 50a of the concave portion by an ink jet process or the like. Subsequently, the applied material is subjected to a heat treatment at a temperature of 300° C., and thereby the semiconductor layer 20 made of amorphous silicon is formed.

At a point in time immediately after the formation of the semiconductor layer 20, it is in a situation where the semiconductor layer 20 is located above the metal foil 70 via the insulating layer 14. Thus, the layer 20 can be subjected to an annealing treatment. Such annealing treatment of the semiconductor layer 20 makes it possible to improve or modify a film quality of the semiconductor layer 20.

In a case where the semiconductor layer 20 made of the amorphous silicon is formed in the concave portion 50, it can be modified to a polycrystalline silicon (for example, the polycrystalline silicon having its average particle diameter of a few hundred nm to about 2 micrometers) by the annealing treatment. In another case of the semiconductor layer 20 made of a polycrystalline silicon, the degree of the crystallization thereof can be improved by the annealing treatment. Moreover, the modification of the film quality of the semiconductor layer 20 can lead to an improved mobility of the semiconductor layer 20. This means that there may be a significant difference in the mobility of the semiconductor layer 20 between the before-annealing and the after-annealing.

In this regard, the brief explanation regarding the relationship between the crystal particle diameter of the silicon semiconductor and the mobility is as follows, for example:

The mobility of a-Si (amorphous silicon) is less than 1.0 cm²/Vs. The mobility of μC-Si (microcrystalline silicon) is about 3 (cm²/Vs), and the crystal particle diameter thereof is in the range of 10 nm to 20 nm. The mobility of pC-Si (polycrystalline silicon) is about 100 (cm²/Vs) or in the range of about 10 to about 300 (cm²/Vs), and the crystal particle diameter thereof is in the range of about 50 nm to about 0.2 μm. Therefore, when the film quality is modified due to the annealing treatment from a-Si (amorphous silicon) to pC-Si (microcrystal silicon) or pC-Si (polycrystalline silicon), the mobility can increase by more than several times (i.e., several times, tens times, hundreds times and so on). Incidentally, the mobility of sC-Si (single crystal silicon) is about 600 (cm²/Vs) or more.

As the annealing treatment of the semiconductor layer, the metal foil 70 provided with the semiconductor layers 20 can be subjected to a heat treatment as a whole. Alternatively, by irradiating the concave portion 50 with the laser light, the semiconductor layer 20 can be subjected to a heat treatment. In a case of the annealing treatment by the laser irradiation, the following procedure may be adopted for example: The semiconductor layer 20 may be irradiated with an excimer laser (XeCl) having a wave length of 308 nm, 100 shots to 200 shots with an energy-density of 50 mJ/cm² and a pulse width of 30 nanoseconds. It should be noted that the specific conditions of the annealing treatment are suitably selected in light of the various factors.

The heat treatment of the insulating film 14 can be simultaneously performed upon the heat treatment of the semiconductor layer 20. In other words, the anneal treatment of the semiconductor layer 20 and the anneal treatment of the insulating film 14 may be simultaneously performed in the same process. The anneal treatment of the semiconductor layer 20 makes it possible to modify the film quality of the gate insulating film 14. In this regard, when the semiconductor layer is heated, the insulating film 14 may also be heated due to the heat thereof. In a case where the insulating film 14 is an oxide film (SiO₂) prepared by a thermal oxidation (wet oxidation) in the steam, the electron trap level of the oxide film (SiO₂) can be reduced by heating of the insulating film 14. Further explained in this regard, the wet oxidation is preferable since the productivity is superior due to an oxidizing velocity being about 10 times as high as that of the dry oxidation. But, the wet oxidation has a tendency that the electron trap level increases. While on the other hand, the dry oxidation has so much hole traps, in spite that the generation of the electronic trap level is lowered. Accordingly, a gate oxide film having fewer electron traps and fewer hole traps can be produced with sufficient productivity by performing, under an oxygen atmosphere, the heat treatment of the oxide film produced by the wet oxidation.

Subsequent to the formation (and the heat treatment) of the semiconductor layer 20, the source electrode 30s and the drain electrode 30d are formed. That is, the step (D) in the manufacturing method of the present invention is performed. First, as shown in FIGS. 3(a) and 3(b), a resist (mask) 72, which defines the shape and the position of the source electrode 30s and the drain electrode 30d, is formed on the semiconductor layer 20 and the insulating film 14. FIG. 3(b) is a top plan view of the structure shown in FIG. 3(a), wherein the semiconductor layer 20 is omitted so as to clearly show the shape of the concave portion 50. Since each opening of the resist 72 corresponds to the region which defines the source electrode 30s and/or the drain electrode 30d, the local part which is covered by the resist 72 and is located between the source electrode 30s and the drain electrode 30d corresponds to the channel region 22.

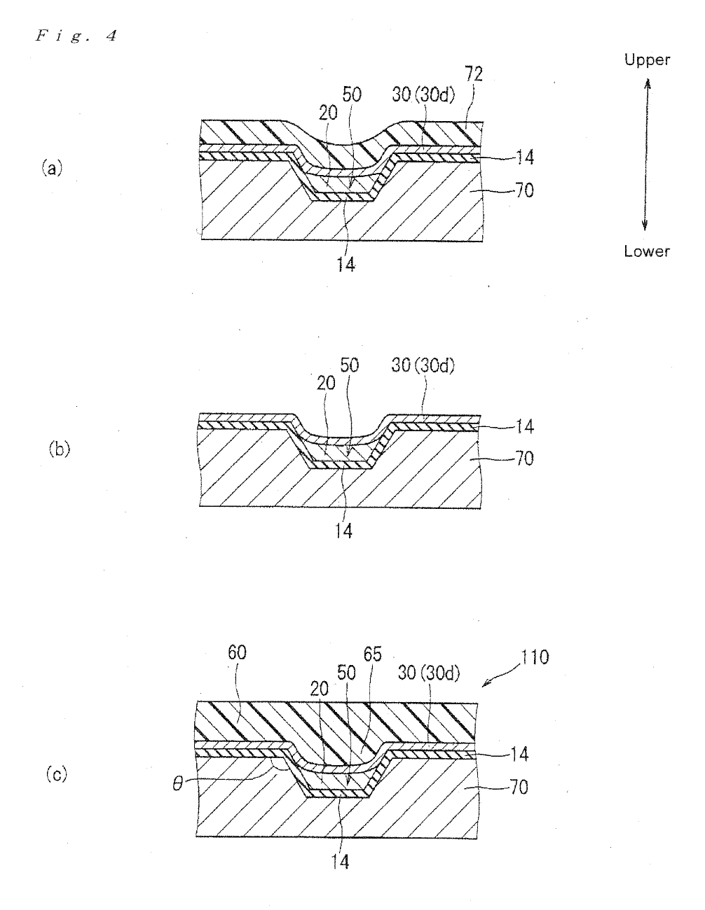

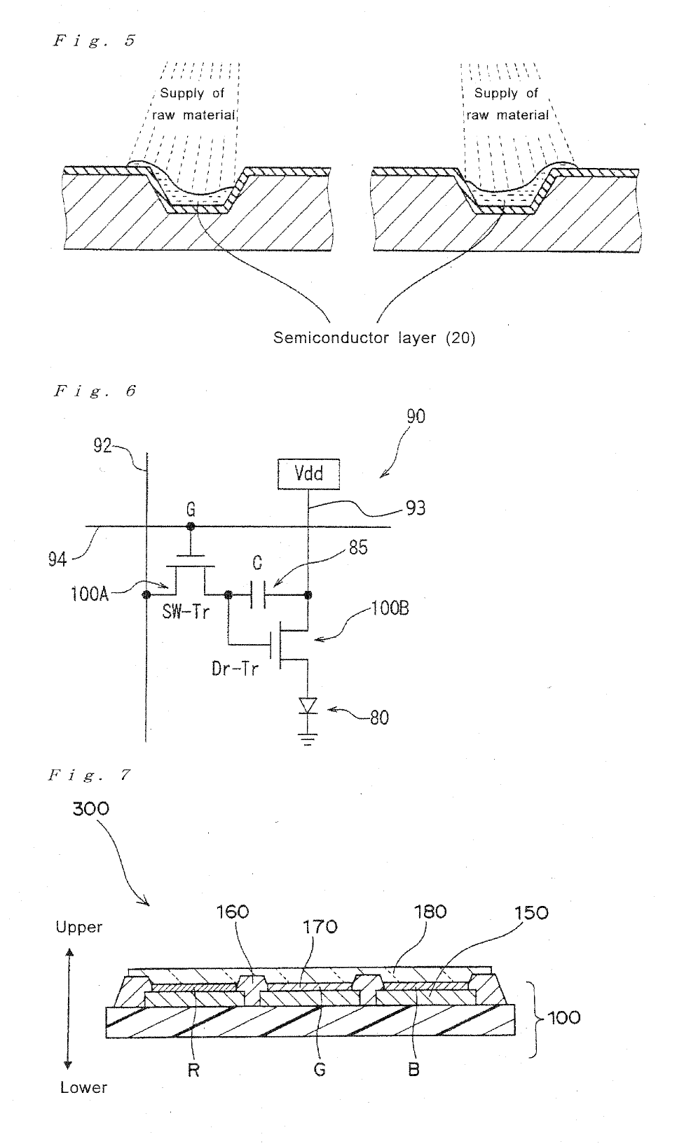

Then, as shown in FIG. 4(a), the source/drain electrodes 30 (30s, 30d) are formed by making use of the resist 72 as a mask. A part of each of the source/drain electrodes 30 contacts with the semiconductor layer 20 provided in the concave portion 50 and the other parts of the electrodes form patterns extending over the insulating layer 14. Each of the source/drain electrodes 30 (30s, 30d) can be typically formed from a metal paste (for example, Ag paste). The formation of the source/drain electrodes 30 can be performed by applying a metal paste by performance of the printing process such as a screen printing process, a gravure printing process, an ink jet method process and the like, as well as by performance of the thin film formation process such as a vacuum deposition process, a sputtering process, a plasma CVD process and the like, and also a plating process. The resist 72 is finally removed as shown in FIG. 4(b), and thereby the source/drain electrodes are provided.

Subsequent to the formation of the source electrode 30s and the drain electrode 30d, the resin film layer 60 is formed as the step (E). That is, the resin film layer 60 is formed over the metal foil 70 so as to cover the source/drain electrodes 30, the semiconductor layer 20 and the insulating layer 14 as shown in FIG. 4(c). As a result, a film-laminated structure (flexible substrate structure) 110 is obtained. According to the present invention, a part of the resin film layer 60 is forced to be inserted into the concave portion 50 upon the formation of the resin film layer 60. That is, the formation of the resin film layer 60 is performed so that the inside of the concave portion 50 is filled with the material body of the resin film. This means that the resin film layer 60 is provided to have the protruding portion 65 which interdigitates with the concave portion 50. Such interdigitate structure between the protruding portion 65 and the concave portion can improve the tight adhesiveness between the resin film layer 60 and the metal foil 70 (i.e., gate structure).

The angle θ (see FIG. 2(b)) of the concave portion 50 is an obtuse angle according to the present invention, and thereby the insertion of a part of the resin film 60 into the concave portion 50 is facilitated as compared with the case where the angle θ is a right angle. This is desirable since the formation of the interfitting (interdigitating) between the protruding portion and the concave portion can be promoted. The further effect of the angle θ of the concave portion 50 being an obtuse angle is that the stress applied to each of the source/drain electrodes 30 at the edge of the concave portion 50 can be reduced compared with the case of the angle θ being a right angle. As a result, there can be obtained a reliability of the source/drain electrodes 30. Moreover, in the case where the angle θ is an obtuse angle, the function of the concave portion 50 as the bank member upon the formation of the semiconductor layer 20 may be further improved compared with the case where the angle θ is a right angle. Specifically, even when the positional precision of the supply device is inferior (or the supply device has significant tolerance) in terms of the supplying of the semiconductor materials into the concave portion 50, the structure where the angle θ is an obtuse angle can improve such positional precision of the formed semiconductor layer 20. The reason for this is that the region for receiving the supplied material can be enlarged due to the presence of the concave portion 50.

Examples of the formation process for the resin film layer 60 include, but not limited to, a process of laminating a semi-cured resin film onto the metal foil 70, followed by being cured (wherein an adhesive material may be applied to a laminating surface of the resin sheet), and a process of applying a resin in liquid form onto the metal foil 70 by the spin-coating or the like, followed by being cured. The thickness of the resin film layer 60 is, for example, in the range of about 4 μm to about 100 μm. In the above case where the semi-cured resin film is laminated, it is pressed during laminating procedure so that a part of the resin film can be inserted into the concave portion 50 of the gate structure, which leads to the interfitting of the part of the resin film layer with the concave portion 50. As the resin film to be used for the lamination, a resin film preliminarily provided with a convex portion having a substantially complementary shape with respect to the concave portion 50 of the gate structure may be used.

In a case where the adhesive material is applied to the laminating surface of a resin sheet, the resin sheet part may have a thickness in the range of about 2 μm to about 100 μm, and the adhesive material part may have a thickness in the range of about 3 μm to about 20 μm. The laminating condition may be appropriately selected depending on the curing properties of the resin film material and the adhesive material. For example, in a case where of the resin film composed of a polyimide film (thickness: about 12.5 μm) and an epoxy resin (thickness: about 10 μm) as the adhesive material applied to the laminating surface thereof, the resin film is laminated onto the metal foil and the laminate thus formed is subject to a tentative pressure bonding under the heating condition of 60° C. and the pressure condition of 3 MPa. Thereafter, the adhesive material is subjected to a substantial curing at the condition of 140° C. and 5 MPa for 1 hour.

The resin film layer 60 thus formed serves to protect the semiconductor layer 20, and thereby a handling or conveying operation in the next step (e.g., patterning treatment of the metal foil 70) can be stably performed.

After the forming of the resin film layer 60, the metal foil 70 of the film-laminated body 110 is subjected to a patterning treatment to form a gate electrode 12 from the metal foil 70. As a result, there can be finally obtained the flexible semiconductor device 100 according to the present invention. In a case where the patterning of the metal foil 70 is performed with respect to the structure as shown in FIG. 4(c), the resin film 60 can serve as a supporting substrate, which makes it possible to perform a suitable patterning treatment.

A flexible semiconductor device in which the resin substrate is used as the supporting substrate has the laminated-body of the different materials (such as different materials of a thin-film transistor), and thus generally has a relatively small adhesive strength at the interface between the layers, which generally poses a problem for the adhesion of the layers. Particularly, the peeling phenomenon tends to occur at the interface between the metal layer and the organic material layer. In the conventional way, there is generally performed a formation of a layer consisting of a silane coupling agent having a high affinity with plastics on the surface of the metal, or an application of an epoxy resin having a lot of polar groups to the adhesive material to be used. This conventional way requires some combination of the specific materials, which can have little choice of the materials. Such limited kind of materials to be used makes the development of the device more difficult since all the conditions of the electrical properties, the heat resistance upon the production process and an environmental stability in a use environment are required to be met. The above problems of the adhesion/peeling become serious in the device with its greater area, considering that a warping occurs at the interface between different materials due to a mismatch of their thermal expansions in the laminated-body made of different materials, or considering that the larger an area of the laminated body becomes, the larger the warping becomes even in the case where the mismatch per unit length is the same. Such problems of the adhesion/peeling become more serious in the roll-to-roll process where the laminated-body is forced to be bent. In this regard, the problems of the peeling off (or detachment) are likely to occur at the interface where the adhesive strength is weak since the degrees of the warping are different between the upper layer and the lower layer in the laminated-body. The present invention can solve or alleviate the above problems, since the improved tight adhesiveness between the resin film layer 60 and the metal foil 70 is provided due to the fact that the protruding portion 65 interdigitates with the concave portion 50 in the flexible semiconductor device 100 of the present invention.

To improve the adhesion between different materials by the interfitting structure (i.e., interdigitating structure), the size and the number of the protruding portion in the interdigitate structure are not particularly limited. However, the larger size the protruding portion has or the more number of the protruding portion the layer 60 has, the higher effect is provided. While on the other hand, when the interdigitate structure is separately and additionally formed in order to improve the adhesion, the areas for the formed transistors and wirings decrease, which can consequently bring disadvantages. In this regard, according to the present invention, there is no need to separately form the interdigitate structure for improving the adhesion since the channel area between the source/drain electrodes 30 (30s, 30d), which is located in the concave portion 50, can serve as the interdigitate structure in the flexible semiconductor device 100. In other words, the larger size the protruding portion 65 has or the more number of the protruding portion 65 (i.e. the concave portion 50) the interdigitate structure has, the higher effect of the adhesion/tight adhesiveness can be provided in the present invention. As for the size of the interdigitate structure in the present invention, the bottom face of the protruding portion is for example in the range of about 1 μm to about 1 mm, and the height of the protruding portion is for example in the range of about 0.5 μm to 100 μm when considering the size of the transistor structure. The surface density of the interdigitate structure can be decided in light of the resolution and the screen size in a case where it is used for an organic electroluminescence display device, for example. Just as an example, in a case where each of RGB pixels is equipped with two transistors in a television (or display) having 100 inches in size, the surface density of the interdigitate structure is about 580 per square inch in the NTSC system (having 720 by 480 pixels) and is about 3460 per square inch in the full high vision system (HD (high definition) system).

(Image Display Device Equipped with the Flexible Semiconductor Device)

With reference to FIG. 6, an embodiment wherein the flexible semiconductor device 100 of the present invention is utilized in an image display device will be explained. The circuit 90 shown in FIG. 6 is a driving circuit which is mounted on an image display device (e.g., organic electroluminescence display), and FIG. 6 shows a constitution of one pixel in the image display device. Each pixel in the image display device according to the present invention comprises a circuit with a combination of two transistors (100A, 100B) and one capacitor 85. This driving circuit includes a switching transistor (hereinafter, referred to as “Sw-Tr”) 100A and a driving transistor (hereinafter, referred to as “Dr-Tr”) 100B, both of which consist of the flexible semiconductor device 100 of the present invention. It is possible that the structure of the flexible semiconductor device 100 is provided with a capacitor 85, in which case the insulating layer 14 in the present invention can be used as a dielectric layer of the capacitor 85.

More specifically, a gate electrode of Sw-Tr 100A is connected to a selection line 94. As for the source electrode and the drain electrode of Sw-Tr 100A, one thereof is connected to a data line 92 and the other thereof is connected to a gate electrode of Dr-Tr 100B. As for the source electrode and the drain electrode of Dr-Tr 100B, one thereof is connected to a power line 93 and the other thereof is connected to a display area 80 (e.g., an organic electroluminescence element). The capacitor 85 is connected to the region between the source electrode and the gate electrode of Dr-Tr 100B.

As for the above pixel circuit, when the switch of Sw-Tr 100A is set “ON” during the activation of the selection line 94, a driving voltage is supplied from data line 92 and selected by Sw-Tr 100A, and thereby the electric charge is stored in the capacitor 85. Then, a voltage resulted from the above charge is applied to the gate electrode of Dr-Tr 100B, and thereby a drain electric current corresponding to the voltage is supplied to the display area 80, which causes the display area (organic electroluminescence element) 80 to emit light.

Next, an embodiment where an image display unit is produced on the transistor or circuit comprising the transistors (particularly, an embodiment about the image display unit composed of a plurality of pixels over the flexible semiconductor device) will be explained.

FIG. 7 is a sectional view of an OLED (organic electroluminescence) image display device 300 wherein three colors consisting of R (red), G (green) and B (blue) are used in three pixels on the flexible semiconductor device of the present invention. The semiconductor device is illustrated only by a resin film and pixel electrodes (cathodes). In such image display device 300, each light emitting layer 170 is arranged on each pixel electrode 150 consisting of R, G and B pixels where the luminescent materials of the light emitting layers respectively correspond to the respective ones of R, G and B. Pixel regulating parts 160 are provided between the adjacent pixels to prevent the adjacent luminescent materials from being intermingled with each other as well as to facilitate the positioning upon the arrangement of the EL materials. A transparent electrode layer (anode layer) 180 is provided over the light emitting layer 170 such that it covers the whole of each pixel.

Examples of the materials to be used for the pixel electrodes 150 include a metal (e.g., Cu). The pixel electrode may have a stacked layer structure composed of a charge injection layer and a surface layer (e.g., Al surface layer with its thickness of 0.1 μm) wherein the charge injection layer functions to improve a charge injection efficiency with respect to the light emitting layer 170, and the surface layer functions to improve a light extraction efficiency in upward direction by reflecting a light emitted from the light emitting layer. In this regard, the pixel electrode may be a reflection electrode with Al/Cu stacked layer structure, for example.

Examples of the material to be used for the light emitting layer 170 include, but not limited to, a polyfluorene-based electroluminescent material and a dendrimer-based light emitting material having a dendritically branched structure wherein at least one heavy metal (e.g., Ir or Pt) is positioned at the center of a dendron backbone of a so-called dendrimer. The light emitting layer 170 may have a single layer structure. Alternatively, the light emitting layer 170 may have a stacked layer structure with an electron injection layer/a light emitting layer/a hole injection layer by using MoO₃ for the hole injection layer (to facilitate the injection of charge) and LiF for the electron injection layer. As the transparent electrode 180 of the anode, ITO may be used.

As for the pixel regulating part 160, it may be made of an insulating material. For example, a photosensitive resin mainly comprising polyimide, or SiN can be used as the insulating material of the pixel regulating part.

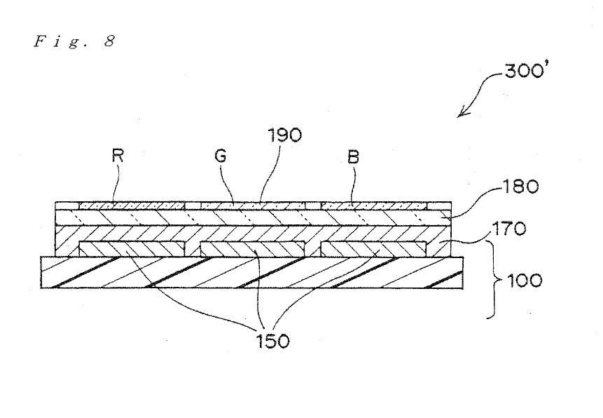

The image display device may be configured to have a structure with a color filter as shown in FIG. 8. The image display device 300′ as shown in FIG. 8 comprises the flexible semiconductor device 100, a plurality of pixel electrodes 150 provided on the flexible semiconductor device 100, a light emitting layer 170 provided such that it wholly covers the pixel electrodes 150, a transparent electrode layer 180 provided on the light emitting layer 170, and a color filter 190 provided on the transparent electrode layer 180. In the image display device 300′, the color filter 190 has a function to convert lights emitted from the light emitting layer 170 to three kinds of lights of red, green and blue, and thereby three kinds of pixels consisting of R(red), G(green) and B(blue) are used. As for the image display device 300 shown in FIG. 7, each of the light emitting layers separated by the pixel regulating parts 160 emits each of red, green and blue lights separately. While on the other hand, as for the image display device 300′ shown in FIG. 8, the light emitted from the light emitting layer has no difference in color (i.e., the light emitting layer emits white light), but the passing of the light through the color filter 190 causes the generation of each of red, green and blue lights.

### (Manufacturing Method of Image Display Device)

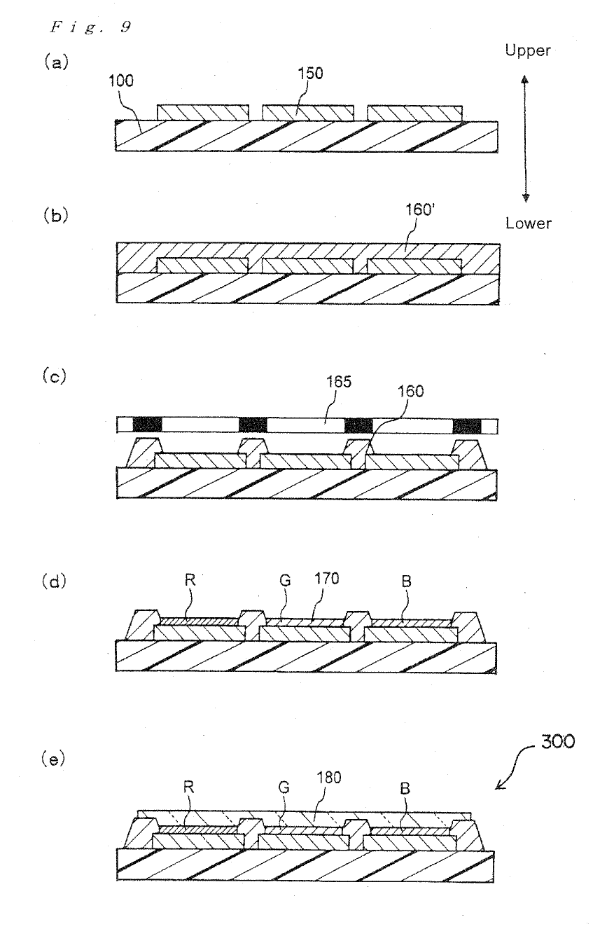

Next, a manufacturing method of the image display device will be explained. Specifically, a manufacturing method of OLED according to the present embodiment will be explained with reference to FIG. 9.

First, the flexible semiconductor device 100 equipped with pixel electrodes 150 is prepared as shown in FIG. 9(a). Specifically, the pixel electrodes 150 can be provided by subjecting the metal foil to a patterning treatment (that is, the pixel electrodes 150 can be formed by etching away the part of the metal foil provided on the flexible film layer by the photolithography process or the like) upon the manufacturing process of the flexible semiconductor device 100. Alternatively, the pixel electrodes 150 can be provided by applying the raw materials for the pixel electrodes by a printing process or the like at predetermined portions upon the manufacturing process of the flexible semiconductor device 100.

Subsequent to the provision of the pixel electrodes, an image display unit composed of a plurality of pixels is formed over the flexible semiconductor device. For example, as shown in FIGS. 9(b) to 9(d), a plurality of pixel regulating parts 160 are formed on the flexible semiconductor device 100, and then each light emitting layer 170 is formed on a region of each pixel electrode 150, the region being partitioned by the pixel regulating parts 160. The pixel regulating parts 160 can be formed, for example, by forming a precursor layer 160′ for the pixel regulating parts wherein the pixel electrodes as a whole are covered with a photosensitive resin material mainly consisting of polyimide, followed by subjecting the precursor layer 160′ to a photolithography process. Light emitting layers 170 of the predetermined colors are respectively formed on the corresponding ones of the pixel electrodes. The light emitting layers 170 can be formed, for example, by applying a solution of a polyfluorene-based electroluminescent material (1%) dissolved into xylene onto the pixel electrodes by performing an ink jet process. The light emitting layer 170 may have a thickness of about 80 nm, for example.

Subsequent to the formation of the light emitting layer 170, a transparent electroconductive layer 180 (e.g., ITO film) is formed so as to cover the light emitting layers 170. The transparent electroconductive layer consisting of the ITO film can be formed by performing a sputtering process.

According to the above processes, there can be finally obtained the image display device 300 having the structures as shown in FIG. 9(e) and FIG. 7.

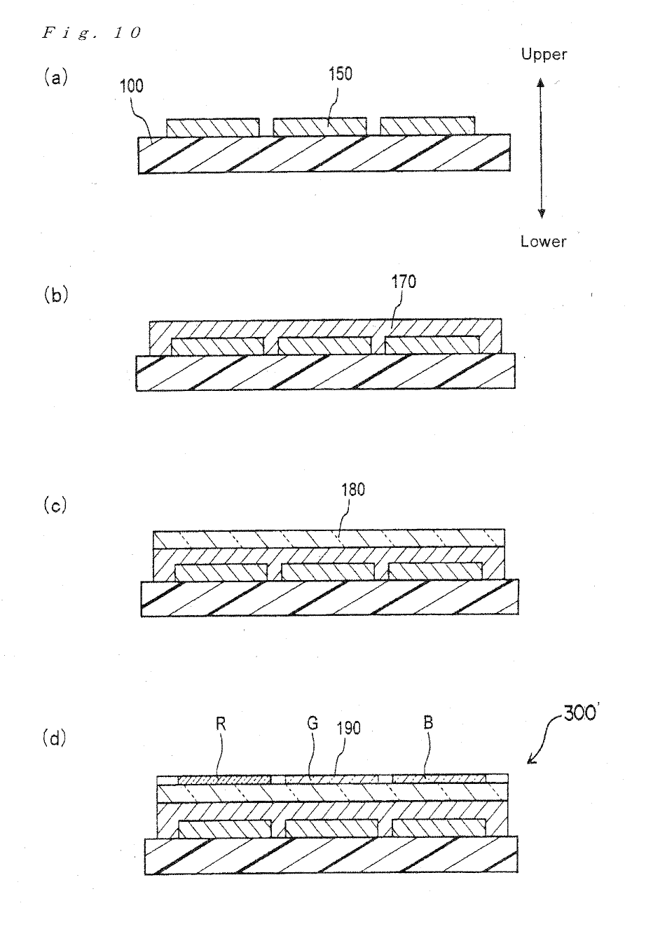

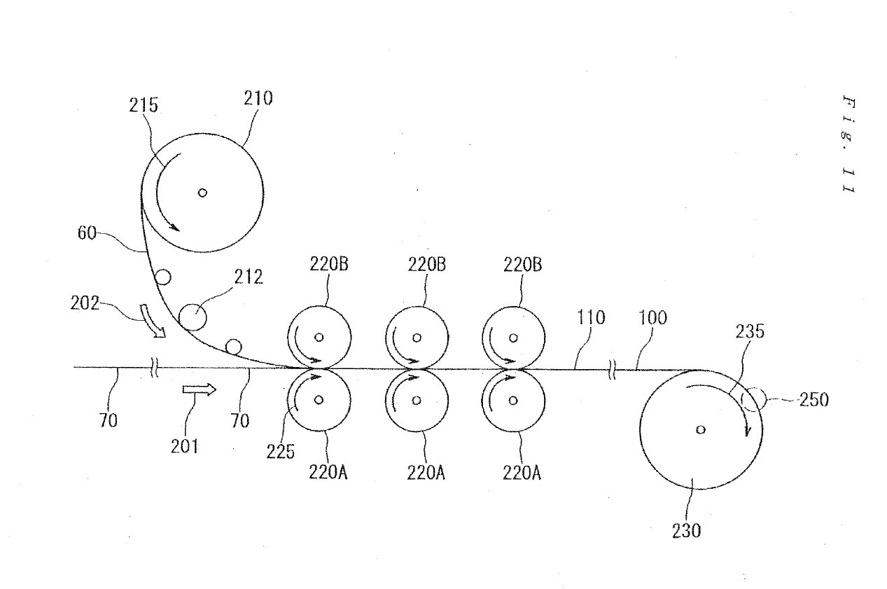

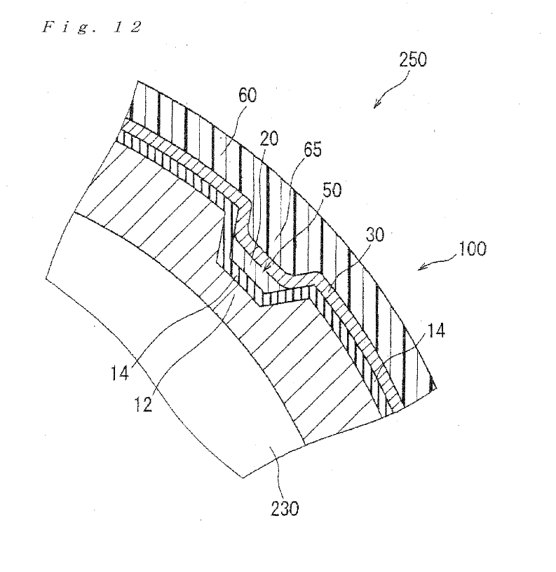

As an alternative embodiment, the manufacturing process of the image display device 300′ equipped with a color filter will now be explained. This manufacturing process is substantially the same as that of the above mentioned manufacturing process, while there are some partial differences. Specifically, after the provision of the pixel electrodes as mentioned above (see, FIG. 10(a)), a light emitting layer 170 capable of emitting white color is wholly laminated in the form of a film (see FIG. 10(b)). Subsequently, a transparent electrode layer 180 is formed in the same manner as mentioned above (see FIG. 10(c)). Thereafter, the color filter 190 capable of emitting R(red), G(green) and B(blue) is formed such that each color of the filter is arranged at each of the corresponding pixel positions (see FIG. 10(d)). As a result of the above processes, there can be finally obtained the image display device 300′.

### (Roll-to-Roll Process)

The flexible semiconductor device 100 of the present invention is “flexible”, and thus it can be suitably manufactured through a roll-to-roll process. FIG. 11 shows an embodiment where the flexible semiconductor device 100 is being manufactured by the roll-to-roll process.

According to the roll-to-roll process, the metal foil on which the semiconductor layers 20—containing transistors (TFT) are provided (that is, the structured bodies as shown in FIG. 4(b) are provided) is conveyed such that it passes a pair of rollers 220A, 220B, together with a resin film 60 as shown in FIG. 11. This passing produces a laminated body 110 wherein the “metal foil 70 provided with the transistors” and the “resin film 60” are integrated with each other (that is, the structure as shown in FIG. 4(c) is provided).

More detailed explanation about this is as follows: The metal foil 70 provided with the transistors (TFT) (the structures as shown in FIG. 4 (b)) is conveyed in the direction of the arrow 201. While on the other hand, the resin film 60, which is unrolled from the roller 210 (see the arrow 215), is conveyed in the direction of the arrow 202 along an auxiliary roller 212. Subsequently, the metal foil 70 and the resin film 60 are laminated so that they are integrated with each other by passing the space between a pair of heating and pressurizing rollers (220A, 220B) which are rotating in the direction of the arrow 225.

Upon the laminating and integrating process of the metal foil and the resin film, a part of the resin film layer 60 (65) is forced to be inserted into the concave portion 50 of the metal foil 70, and thereby the interdigitate structure is formed. After the completion of the laminating and integrating process, the metal foil laminated with the resin film 110 (i.e., the film laminate) is sent to the etching process wherein the metal foil 70 is subjected to a patterning treatment (not shown) to obtain the flexible semiconductor device 100. The flexible semiconductor device 100 thus obtained is finally wound up by the roller 230 (see arrow 235).

FIG. 12 shows a sectional view of a part 250 of the flexible semiconductor device 100 which has been wound up by the roller 230. As shown in FIG. 12, the gate electrode 12 (i.e., the patterned metal foil 70) is positioned inside and the supporting substrate (i.e., the resin film) 60 is positioned outside around the roller 230, which leads to a compression of the gate structure 12 as well as a stretching of the supporting substrate 60. As a result, the degree of the warping of the gate structure 12 becomes different from that of the supporting substrate 60, which can generate any sheer stress on the interface therebetween, and thereby inducing the peeling phenomenon in the laminated structure. In the case of the conventional laminated structure, the generation of the peeling phenomenon is suppressed only by the adhering strength between the gate structure 12 (the patterned metal foil 70) and the supporting substrate 60. In this regard, according to the present invention, the laminated structure is strongly held by the interdigitate structure (50, 65) in addition to the adhesion strength, so that the tight adhesiveness is improved, which can lead to a prevention or reduction of the occurrence of the peeling phenomenon.

In the embodiment shown in FIG. 11, the flexible semiconductor device 100 is wound up by the roller 230. In this regard, it is possible to adopt additional step wherein the metal foil 70 is subjected to an etching process to form the gate electrode 12 in a separate process after such winding up by the roller 230. Alternatively, it is also possible to unroll the metal foil 70 from a roller provided at an initial stage (not shown) and is sequentially subjected to all the processes (or a part thereof) shown in FIG. 2(a) to FIG. 4(c) by means of rollers, a chamber, an etching bath and the like.

### (Modification of Semiconductor Layer)

As mentioned in the above, the modification of the semiconductor layer can be easily and effectively performed according to the present invention. Particularly, it is possible to perform the modification of the semiconductor layer 20 made of an oxide semiconductor. For example, in a case of the crystalline oxide semiconductor such as ZnO, there are relatively large amount of amorphous state in the crystalline layer immediately after being formed as a film by a sputtering and the like, and thereby frequently failing to show the properties of the semiconductor (i.e., performance of the semiconductor device). However, according to the present invention, the device as shown in FIG. 2(d), that is, the device where the concave portion 50 is filled with the semiconductor material (i.e., the oxide semiconductor in this case) has a structure composed of the metal foil 70, the insulating layer 14 and the semiconductor material 20 (i.e., the structure with no resin film) while being flexibility, and thereby the annealing process or laser irradiation process can be performed without significant restrictions. The performing of the annealing process or laser irradiation process can improve the crystallinity of the oxide semiconductors (e.g., ZnO), which leads to an improved performance of the semiconductor.

As an example regarding the above, when ZnO is formed by a RF magnetron sputtering process in the order of the formations of ZnO film (50 nm) and SiO₂ film (50 nm), the formed layer does not show the properties of the semiconductor at the point time before the irradiating with excimer laser. While on the other hand, after the irradiation with XeCl excimer laser is performed, the layer become capable of functioning as the semiconductor and thus it can have a mobility of about 20 cm²/Vs.

Also as for the amorphous oxide semiconductor such as InGaZnO, the effects of improving the semiconductor properties can be provided. In the case of the amorphous oxide semiconductor, an oxygen deficiency can be restored and thus the mobility can be improved due to the laser irradiation under the oxygen atmosphere (for example, air atmosphere) and also under such a condition that the concave portion 50 is filled with the semiconductor material (i.e., amorphous oxide semiconductor material). When the TFT is produced using InGaZnO as the semiconductor material, the very low mobility before the laser irradiation can be increased to the degree of about 10 cm²/Vs after the laser irradiation.

Moreover, an electroconductivity control of the oxide semiconductor can be performed. More oxygen deficiency means that there may exist many conduction electrons (that is, the carrier concentration is high), and thus means that the electroconductivity is high. In order to restore the oxygen deficiency (i.e. in order to introduce oxygen), it is suitable to expose the oxide semiconductor to an oxygen atmosphere at a high temperature. Instead of the high temperature, it is also suitable to apply the energy to the oxide semiconductor in the energy form of laser, plasma, ozone or the like.

As an example regarding the above, the electroconductivity control of the oxide semiconductor can be performed by selectively annealing the channel area 22 with laser under the oxygen atmosphere after the filling of the concave portion 50 with the semiconductor material (i.e., oxide semiconductor material in this case, and the material has the more oxygen deficiency at the point time when before the annealing treatment). Alternatively, the electroconductivity control of the channel area 22 can be performed after the formation of the source/drain electrodes 30 (30s, 30d) which contact with the semiconductor layer 20 in the concave portion 50 (see, for example, the structure as shown in FIG. 4(b)) by annealing the transistor structure containing the semiconductor layer 20 as a whole with laser by making use of the source/drain electrodes 30 as a mask.

In order to control the electroconductivity of the oxide semiconductor, further another process is also possible wherein the filling of the concave portion 50 with the semiconductor material (i.e., oxide semiconductor material) (the material having the more oxygen deficiency) is performed, and then the whole thereof is subjected to an annealing treatment under the oxygen atmosphere (and thereby the oxygen deficiency is lowered), followed by the portion of the source/drain electrodes 30 (30s, 30d) being subjected to a laser annealing treatment under a reductive atmosphere. Still further another process is also possible wherein a mask is formed on a portion corresponding to the channel area 22, and then the whole thereof including the mask is subjected to the laser annealing treatment under the reductive atmosphere. With the H plasma (hydrogen plasma) treatment, the atmosphere becomes reductive, thereby facilitating the generation of the oxygen deficiency in the oxide semiconductor.

In general, the present invention as described above includes the following aspects:

The first aspect: A flexible semiconductor device comprising a gate structure composed of a gate electrode formed of a metal foil and a gate insulating film provided on the gate electrode,

wherein a concave portion (depressed portion) serving as a bank member (bank portion) is provided in a surface region of the gate structure;

a semiconductor layer is provided over a bottom face of the concave portion; and

a source electrode and a drain electrode are in a contact with the semiconductor layer.

The second aspect: The flexible semiconductor device according to the first aspect, wherein the concave portion has a tapered shape in which an angle between a sidewall face of the concave portion and a top face extending continuously from the sidewall face is an obtuse angle.

The third aspect: The flexible semiconductor device according to the first or second aspect, wherein a resin film layer having flexibility is provided over the gate structure such that the semiconductor layer, the source electrode and the drain electrode are covered with the resin film layer.

The fourth aspect: The flexible semiconductor device according to the third aspect, wherein the resin film layer has a protruding portion which is in an interdigitate form with respect to the concave portion of the gate structure.

The fifth aspect: The flexible semiconductor device according to the fourth aspect, wherein the protruding portion of the resin film layer and the concave portion of the gate structure are in complementary form with respect to each other.

The sixth aspect: The flexible semiconductor device according to any one of the first to fifth aspects, wherein the semiconductor layer comprises silicon.

The seventh aspect: The flexible semiconductor device according to any one of the first to fifth aspects, wherein the semiconductor layer comprises an oxide semiconductor.

The eighth aspect: The flexible semiconductor device according to the seventh aspect, wherein the oxide semiconductor is a ZnO or InGaZnO semiconductor.

The ninth aspect: The flexible semiconductor device according to any one of the first to eighth aspects, wherein the gate insulating film is made of an inorganic material.

The tenth aspect: The flexible semiconductor device according to any one of the first to eighth aspects, wherein the gate electrode comprises a valve metal; and

the gate insulating film is an anodically-oxidized film of the valve metal.

The eleventh aspect: An image display device using the flexible semiconductor device according to any one of the first to tenth aspects, the image display device comprising:

the flexible semiconductor device; and

an image display unit composed of a plurality of pixels, the unit being provided over the flexible semiconductor device,

wherein the concave portion serving as the bank member is provided in the surface region of the gate structure of the flexible semiconductor device; and

the semiconductor layer of the flexible semiconductor device is provided over the bottom face of the concave portion.

The twelfth aspect: The image display device according to the eleventh aspect, wherein the image display unit comprises:

a pixel electrode provided on the flexible semiconductor device;

a light emitting layer provided over the pixel electrode; and

a transparent electrode layer provided on the light emitting layer.

The thirteenth aspect: The image display device according to the twelfth aspect, wherein the light emitting layer is provided at a region partitioned by a pixel regulating part.

The fourteenth aspect: The image display device according to the twelfth aspect, wherein a color filter is provided on the transparent electrode layer.

The fifteenth aspect: A method for manufacturing a flexible semiconductor device, the method comprising the steps of:

(A) preparing a metal foil having a concave portion;

(B) forming a gate insulating film on a bottom face of the concave portion;

(C) forming a semiconductor layer over the bottom face of the concave portion of the metal foil via the gate insulating film while making use of the concave portion as a bank member; and

(D) forming a source electrode and a drain electrode such that they make contact with the semiconductor layer.

The sixteenth aspect: The method according to the fifteenth aspect, wherein the concave portion is formed to have a tapered shape by subjecting the metal foil to a photolithography process and a wet etching process in the step (A).

The seventeenth aspect: The method according to the fifteenth or sixteenth aspect, further comprising a step (E) performed after the step (D),

the step (E) being one for forming a resin film layer having flexibility on the metal foil such that the resin film layer covers the semiconductor layer, the source electrode and the drain electrode.

The eighteenth aspect: The method according to the seventeenth aspect, wherein, in the step (E), a resin film is laminated over the metal foil, and thereby forcing a part of the resin film to interdigitate with the concave portion.

The nineteenth aspect: The method according to the seventeenth or eighteenth aspect, wherein the step (E) is performed by a roll-to-roll process.

The twentieth aspect: The method according to any one of the seventeenth to nineteenth aspects, wherein, after the step (E), the metal foil is subjected to a pattering process, and thereby forming a gate electrode from the metal foil.

The twenty-first aspect: The method according to any one of the fifteenth to twentieth aspects, wherein, after the step (C), the semiconductor layer formed above the metal foil is subjected to a heat treatment.

The twenty-second aspect: The method according to any one of the fifteenth to twenty-first aspects, wherein, in the step (B), the gate insulating film is formed through a sol-gel process.

The twenty-third aspect: The method according to any one of the fifteenth to twenty-second aspects, wherein, after the step (B), the gate insulating film is subjected to a heat treatment.

The twenty-fourth aspect: A method for manufacturing an image display device using the flexible semiconductor device according to any one of the first to tenth aspects,

(I) providing the flexible semiconductor device equipped with a pixel electrode; and

(II) forming an image display unit composed of a plurality of pixels over the flexible semiconductor device.

The twenty-fifth aspect: The method according to the twenty-fourth aspect, wherein, in the step (II), a plurality of pixel regulating parts are formed, and then the pixels are formed on regions of the pixel electrode, the regions being partitioned by the pixel regulating parts.

The twenty-sixth aspect: The method according to the twenty-fourth aspect, wherein, in the step (II), a light emitting layer is formed over the pixel electrode such that the light emitting layer covers the pixel electrode, and then a color filter is formed on the light emitting layer.

Although a few embodiments of the present invention have been hereinbefore described, the present invention is not limited to these embodiments. It will be readily appreciated by those skilled in the art that various modifications are possible without departing from the scope of the present invention.

As an additional remark, the functions of each component of the flexible semiconductor device of the present invention will be briefly explained. Each component of the flexible semiconductor device of the present invention is configured to be suitably available as the TFT (thin-film transistor). Although it is conceivable that a person skilled in the art can understand the operating principle of the TFT and the functions of each component thereof, they are as follows, especially regarding the present invention: Usually, a source electrode is in a state of zero potential and a necessary voltage is applied to a drain electrode. A semiconductor layer is provided in an area between the source electrode and the drain electrodes, which area is called as “channel area”. The channel area is provided on a gate structure to contact with a gate insulating film. The gate structure is composed of the gate insulating film and a gate electrode. The applying of a voltage to the gate electrode can cause the electrical resistance of the channel area to change, and thereby changing a current value flowing between the source electrode and the drain electrode. This is a basic operating principal of the TFT and the functions of each component thereof. While the resin film does not directly relate to the operating of the above TFT, it performs the function to protect the components of the TFT (e.g., the source electrode) by sealing them, the function as the supporting substrate which mechanically holds the components of the TFT (e.g., the source electrode), and the function to provide the whole of semiconductor device with flexibility by the flexible property that the resin film itself has, and thereby ensuring the flexibility of the flexible semiconductor device.

### INDUSTRIAL APPLICABILITY

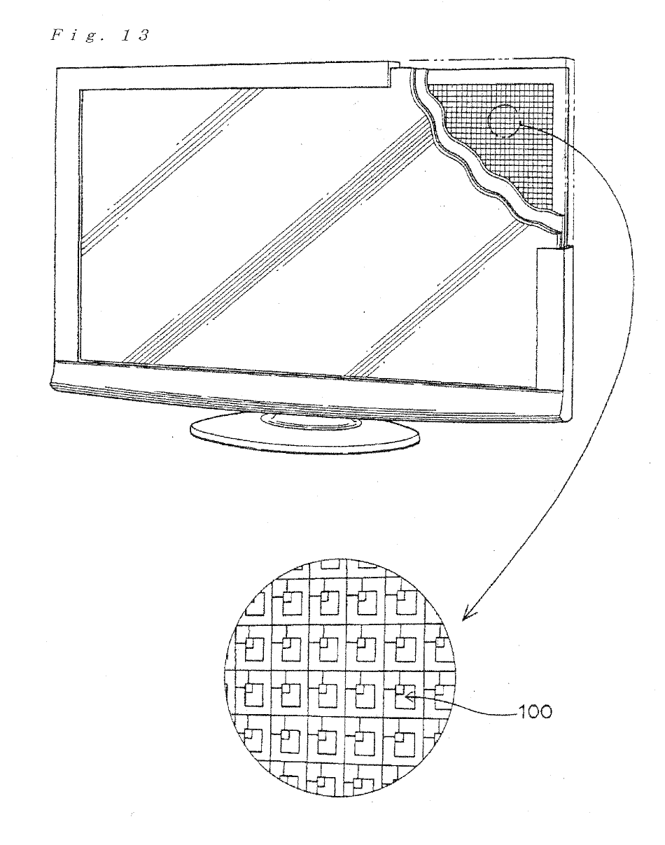

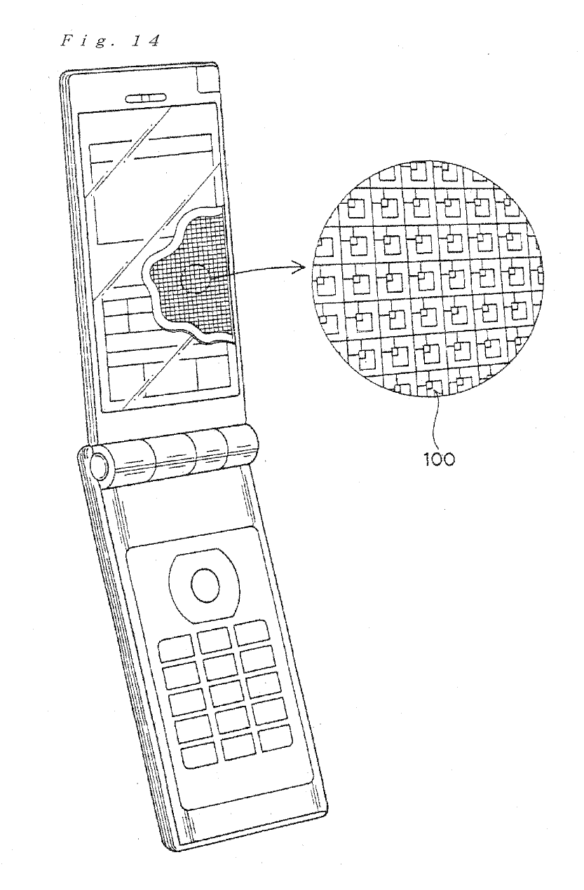

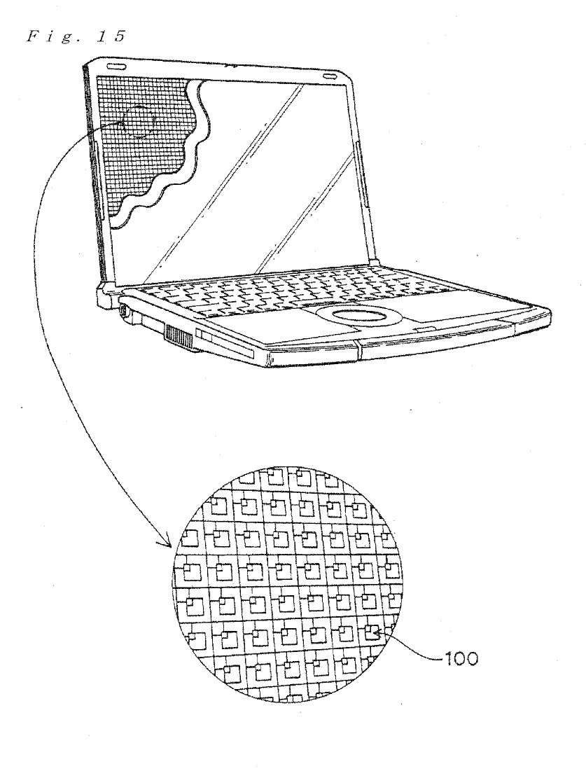

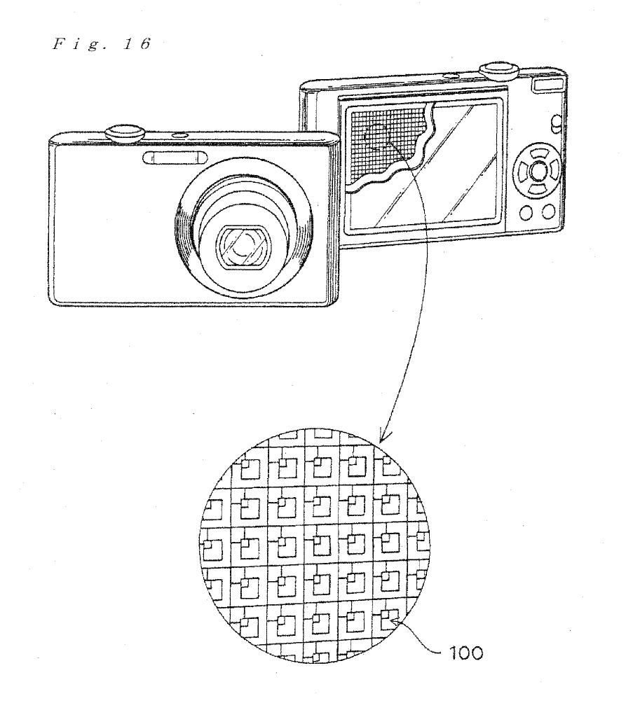

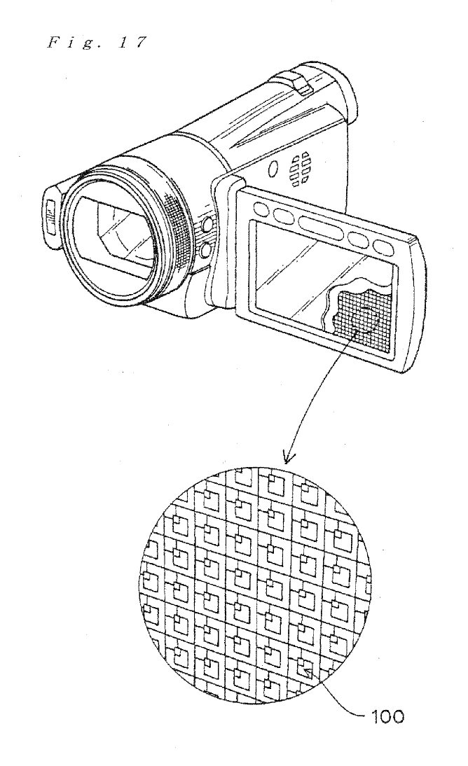

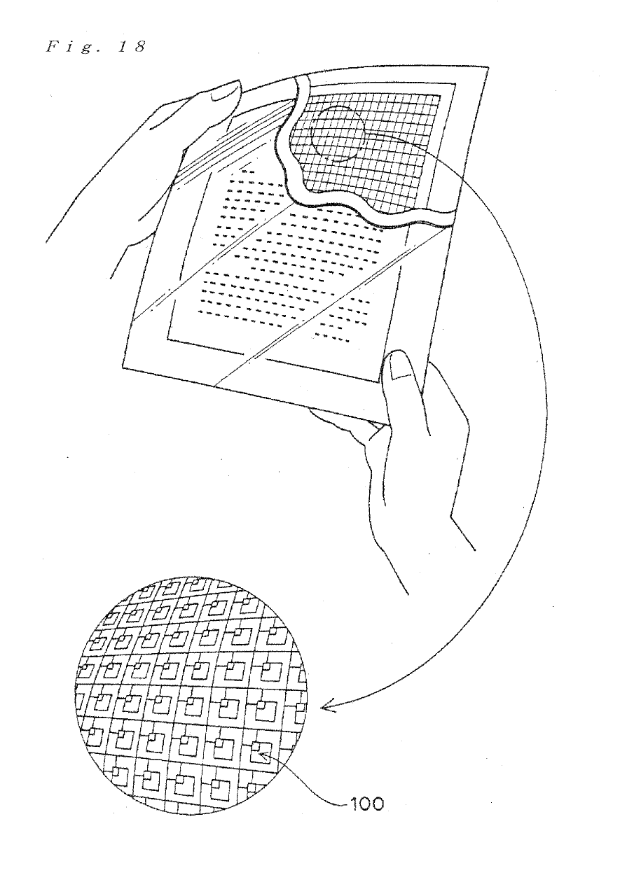

The manufacturing method of the flexible semiconductor device of the present invention is excellent in the productivity of a flexible semiconductor device. The resulting flexible semiconductor device can also be used for various image display parts, and also can be used for an electronic paper, a digital paper and so forth. For example, the flexible semiconductor device can be used for a television picture indicator as shown in FIG. 13, the image display part of a cellular phone as shown in FIG. 14, the image display part of a mobile personal computer or a notebook computer as shown in FIG. 15, the image display part of a digital still camera and a camcorder as shown in FIGS. 16 and 17, the image display part of an electronic paper as shown in FIG. 18 and so forth. The flexible semiconductor device obtained by the manufacturing method of the present invention can also be adapted for the various uses (for example, RF-ID, a memory, MPU, a solar battery, a sensor and so forth) which application is now considered to be adapted by the printing electronics.

### CROSS REFERENCE TO RELATED PATENT APPLICATION

The present application claims the right of priority of Japan patent application No. 2010-112316 (filing date: May 14, 2010, title of the invention: FLEXIBLE SEMICONDUCTOR DEVICE AND METHOD FOR MANUFACTURING THE SAME), the whole contents of which are incorporated herein by reference.

### EXPLANATION OF REFERENCE NUMERALS

10 Gate structure
12 Gate electrode
14 Gate insulating film (insulating layer)
20 Semiconductor layer
22 Channel area
30s Source electrode
30d Drain electrode
50 Concave portion
50a Bottom face (bottom surface)
50b Sidewall face (sidewall surface)
50c Top face (top surface)
60 Resin film (supporting substrate)
65 Protruding portion
70 Metal foil
72 Resist (resist layer/resist pattern)
80 Display area (organic electroluminescence element)
85 Capacitor
90 Driving circuit
92 Data line
94 Selection line
100 Flexible semiconductor device
110 Film-laminated body
150 Pixel electrode (picture electrode)
160 Pixel regulating part
160′ Precursor layer for the pixel regulating part
165 Photomask used for formation of pixel regulating part
   170 Light emitting layer
   180 Transparent electrode layer
   190 Color filter
   210 Roller
   212 Auxiliary roller
   220A, 220B Pressurizing roller
   230 Roller
   250 Part of flexible semiconductor device
   300 Image display device
   300′ Image display device

1. A flexible semiconductor device comprising a gate structure composed of a gate electrode formed of a metal foil and a gate insulating film provided on the gate electrode,
wherein a concave portion serving as a bank member is provided in a surface of the gate structure;
a semiconductor layer is provided over a bottom face of the concave portion; and
a source electrode and a drain electrode are in a contact with the semiconductor layer.

2. The flexible semiconductor device according to claim 1, wherein the concave portion has a tapered shape wherein an angle between a sidewall face of the concave portion and a top face extending continuously from the sidewall face is an obtuse angle.

3. The flexible semiconductor device according to claim 1, wherein a resin film layer having flexibility is provided over the gate structure such that the semiconductor layer, the source electrode and the drain electrode are covered with the resin film layer.

4. The flexible semiconductor device according to claim 3, wherein the resin film layer has a protruding portion which is interfitted with the concave portion of the gate structure.

5. The flexible semiconductor device according to claim 4, wherein the protruding portion of the resin film layer and the concave portion of the gate structure are in complementary form with respect to each other.

6. The flexible semiconductor device according to claim 1, wherein the semiconductor layer comprises silicon.

7. The flexible semiconductor device according to claim 1, wherein the semiconductor layer comprises an oxide semiconductor.

8. The flexible semiconductor device according to claim 7, wherein the oxide semiconductor is ZnO or InGaZnO semiconductor.

9. The flexible semiconductor device according to claim 1, wherein the gate insulating film is made of an inorganic material.

10. The flexible semiconductor device according to claim 1, wherein the gate electrode comprises a valve metal; and
the gate insulating film is an anodically-oxidized film of the valve metal.

11. An image display device using the flexible semiconductor device according to claim 1, the image display device comprising:
the flexible semiconductor device; and
an image display unit composed of a plurality of pixels, the unit being provided over the flexible semiconductor device,
wherein the concave portion serving as the bank member is provided in the surface of the gate structure of the flexible semiconductor device; and
the semiconductor layer of the flexible semiconductor device is provided over the bottom face of the concave portion.

12. A method for manufacturing a flexible semiconductor device, the method comprising the steps of:
(A) preparing a metal foil having a concave portion;
(B) forming a gate insulating film on a bottom face of the concave portion;
(C) forming a semiconductor layer over the bottom face of the concave portion of the metal foil via the gate insulating film while making use of the concave portion as a bank member; and
(D) forming a source electrode and a drain electrode such that they make contact with the semiconductor layer.

13. The method according to claim 12, wherein the concave portion having a tapered shape is formed by subjecting the metal foil to a photolithography process and a wet etching process in the step (A).

14. The method according to claim 12, further comprising a step (E) performed after the step (D),
the step (E) being for forming a resin film layer having flexibility on the metal foil such that the resin film layer covers the semiconductor layer, the source electrode and the drain electrode.

15. The method according to claim 14, wherein, in the step (E), a resin film is laminated over the metal foil, and thereby a part of the resin film interfits with the concave portion.

16. The method according to claim 14, wherein the step (E) is performed by a roll-to-roll process.

17. The method according to claim 14, wherein, after the step (E), the metal foil is subjected to a pattering process, and thereby forming a gate electrode from the metal foil.

18. The method according to claim 12, wherein, after the step (C), the semiconductor layer formed above a layer of the metal foil is subjected to a heat treatment.

19. The method according to claim 12, wherein, in the step (B), the gate insulating film is formed by a sol-gel process.

20. The method according to claim 12, wherein, after the step (B), the gate insulating film is subjected to a heat treatment.
